(19) United States
(12) Patent Application Publication
(10) Pub. No.: US 2002/0025775 A1
(43) Pub. Date: Feb. 28, 2002

(54) Working enclosure with propeller for making its atmosphere move and corresponding propeller

(76) Inventor: Michel Herbreteau, Mortagne Sur Sevre (FR)

Correspondence Address: LARSON & TAYLOR, PLC, 1199 NORTH FAIRFAX STREET, SUITE 900, ALEXANDRIA, VA, 22314, US

(21) Appl. No.: 09/916,221

(22) Filed: Jul. 27, 2001

(30) Foreign Application Priority Data
Jul. 31, 2000 (FR) 0010078

(51) Int. Cl. H05K 5/00

(52) U.S. Cl. 454/184; 454/186

(57) ABSTRACT

This working enclosure (1) comprises at least one envelope (5) delimiting the inside of a working chamber (7), and at least one fan (10) for making the atmosphere of the working chamber move, the fan comprising a propeller (11), placed inside the working chamber in order to rotate about an axis of rotation (A), and a motor with a rotating magnetic field comprising a rotor mounted so as to rotate with the propeller as one piece and made to rotate by the rotating magnetic field. The propeller forms the rotor and rests on a support surface (28) located in the working chamber (7).

The present invention relates to a working enclosure, of the type comprising at least one envelope delimiting the inside of a working chamber, and at least one fan for making the atmosphere of the working chamber move, the fan comprising a propeller, which is placed inside the working chamber in order to rotate about a geometrical axis of rotation, and a motor with a rotating magnetic field comprising a rotor mounted so as to rotate with the propeller as one piece and made to rotate by the rotating magnetic field.

The invention is applicable especially to thermostatted enclosures such as furnaces, autoclaves or incubators. Such enclosures are used, for example, for biological applications such as the culture of bacteria, cells or other organisms, or for baking or solvent-extraction applications.

These enclosures have heating elements generally in the form of electrical resistors. The fan makes it possible to improve the heat transfer between these heating elements and the atmosphere of the working chamber by creating forced convection.

Generally, the drive motor is a motor supplied electrically and comprising a stator for producing a rotating magnetic field. This stator is placed, with the rotor, outside the working chamber. A shaft, which passes through the envelope delimiting the working chamber, then mechanically connects the propeller and the rotor.

Such an arrangement hampers cleaning operations, and more particularly, decontamination operations of the working chamber.

One aim of the invention is to solve this problem by providing a working chamber of the aforementioned type, in which cleaning of the working chamber is made easier.

To this end, the subject of the invention is an enclosure of the aforementioned type, characterized in that the propeller forms the rotor.

According to particular embodiments of the invention, the working enclosure may include one or more of the following characteristics, taken in isolation or in any technically possible combination:

the propeller comprises blades, the upper surfaces of which are inclined at least partially with respect to its axis of rotation in order to produce a local partial vacuum above the propeller, tending to lift it;

the chamber comprises means for indexing the position of the propeller with respect to the support surface;

the propeller rests freely on at least one support located in the working chamber;

the propeller rests directly on the said support which provides the said support surface;

the enclosure comprises at least one shelf placed in the working chamber, the shelf comprising a lower wall and an upper wall between which the propeller is housed, the lower wall providing the said support surface;

the propeller rests on the support via the lower wall of the shelf;

the chamber comprises at least one element for heating the atmosphere of the enclosure of the working chamber;

the enclosure comprises at least one element for cooling the atmosphere of the working chamber;

the drive motor comprises a stator for producing a rotating magnetic field in order to make the propeller rotate;

the stator is placed outside the working chamber; and

the propeller comprises at least one permanent magnet.

In addition the subject of the invention is a propeller for an enclosure as defined above, characterized in that it comprises at least one permanent magnet.

The invention will be better understood on reading the following description, given solely by way of example, and made with reference to the appended drawings, in which:

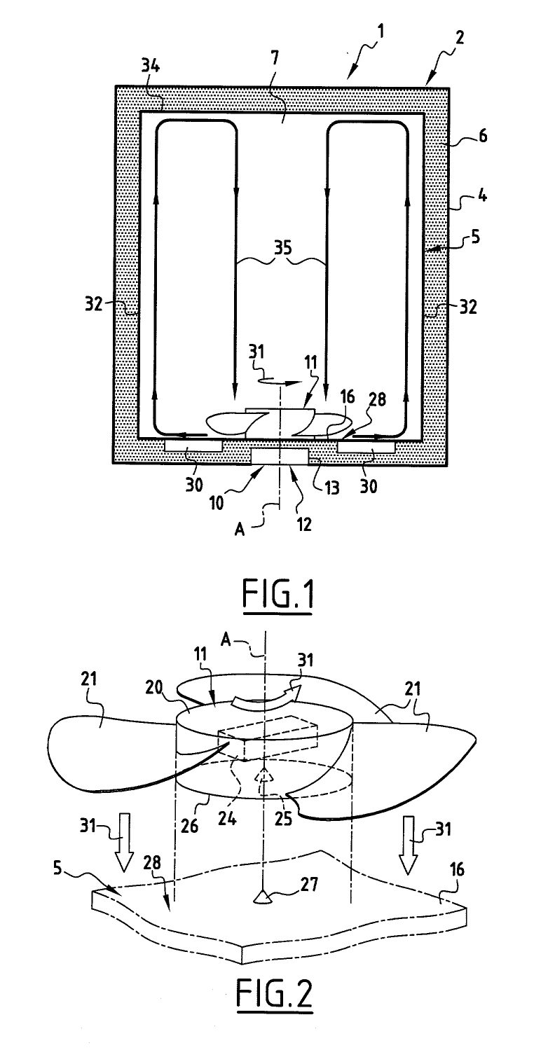

FIG. 1 is a schematic transverse section of an enclosure according to the invention taken along a vertical plane parallel to the opening for access to the enclosure,

FIG. 2 is a partial schematic view in exploded perspective, illustrating the propeller and the bottom of the enclosure of FIG. 1,

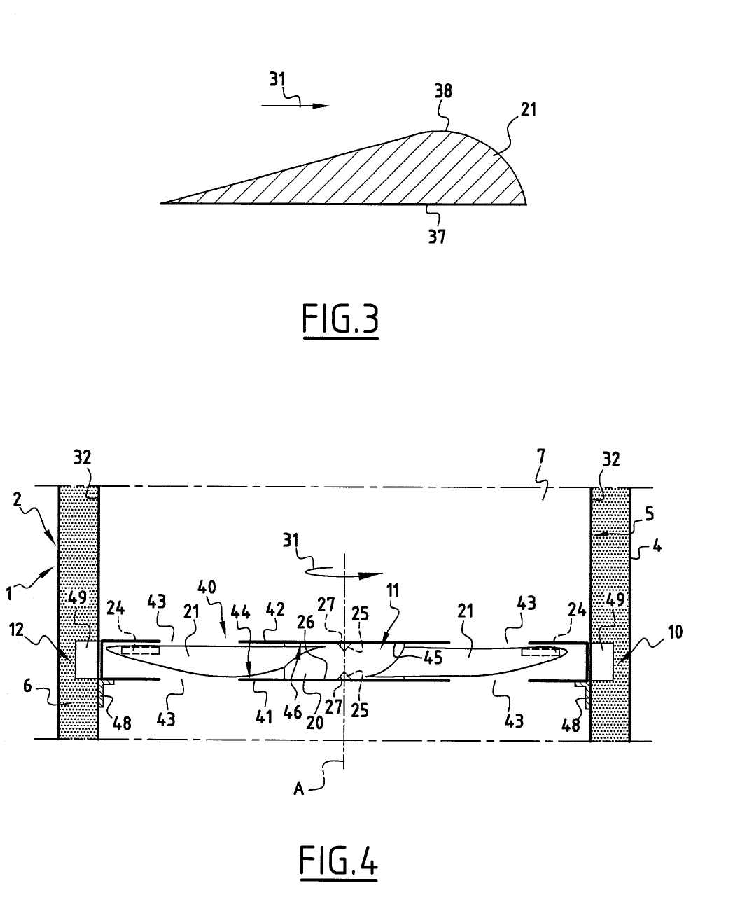

FIG. 3 is a schematic section of a blade of a variant of the propeller of FIGS. 1 and 2, and

FIG. 4 is a partial enlarged view similar to FIG. 1, illustrating another embodiment of the invention.

FIG. 1 shows a working enclosure 1 comprising a substantially parallelepipedal vessel 2, one of the faces of which is open. The enclosure 1 also comprises a door, not shown in FIG. 1, hinged to the vessel 2 in order to close this open face and allow access to the inside of the enclosure 1.

The vessel 2 and the door have a double-envelope structure comprising an outer envelope 4, an inner envelope 5 and a layer of thermal insulation 6 placed between these envelopes.

The inner envelope 5 delimits a working chamber 7 on the inside.

The enclosure 1 is equipped with a fan 10 for making the atmosphere of the working chamber 7 move. This fan 10 comprises a propeller 11 placed inside the working chamber 7 and means 12 for creating a magnetic field, which rotates about a vertical geometrical axis A and which is substantially orthogonal to the latter. Typically, these means 12 may comprise windings through which polyphase currents are designed to pass in order to create the rotating magnetic field. In a variant, these means 12 may comprise a permanent magnet driven by a motor.

The means 12 are housed, under the lower wall or bottom 16 of the inner envelope 5, in a housing 13 made in the thermal insulation 6 and in the outer envelope 4 in order to allow access to these means 12 from the outside of the chamber 1. The vertical axis A is substantially centred with respect to the bottom 16.

As illustrated more particularly by FIG. 2, the propeller 11 comprises a hub 20 with axis A and blades 21 extending radially outwards from this hub 20. These blades 21 are uniformly distributed angularly about the hub 20 and are inclined with respect to the axis A of the hub 20.

A permanent magnet 24 is housed inside the hub 20 so as to rotate as one piece with the latter about the axis A. This permanent magnet 24 is oriented so that the magnetic field which it creates is substantially orthogonal to the axis A.

In addition, the hub 20 has a central conical cavity 25 made in its lower face 26 and converging upwards.

A projection of complementary shape 27 is provided in the centre of the upper surface 28 of the bottom 16 of the inner envelope 5. This projection 27 is oriented upwards.

The propeller 11 rests freely via its hub 20 on the upper surface 28 of the bottom 16. The projection 27 of the bottom 16 is inserted in the cavity 25 of the hub 20.

Heating means 30, such as heating resistors, are fitted under the bottom 16, in the thermal insulation 6.

When the means 12 produce a magnetic field rotating in the direction of the arrow 31 in FIGS. 1 and 2, the field makes the permanent magnet 24, and therefore the propeller 11, rotate in the same direction about the axis A. The means 12 and the propeller 11 then form a stator, located outside the working chamber, and a rotor, respectively, of one and the same motor with a rotating magnetic field.

Because of the orientation of the blades 21 of the propeller 11, the propeller 11 creates a local flow of air directed downwards and therefore towards the bottom 16 as schematized by the arrows 31 in FIG. 2. This flow is therefore directed in the direction of gravity and creates a partial vacuum above the blades 21.

Thus, the propeller 11 tends to lift with respect to the bottom 16 on which it rests, thereby limiting friction.

The bottom 16 then sends the flow of air laterally outwards above the heating elements 30. The flow of air is then deflected upwards by the side walls 32 of the inner envelope 5, then circulated along the upper wall 34 towards its centre, and finally, it descends back towards the propeller 11.

The path of this airflow is schematized by the two arrows 35 in FIG. 1.

Thus, the fan 10 creates a forced convection in the working chamber 7 making it possible to provide satisfactory heat transfer between the heating elements 30 and the atmosphere of this working chamber. In particular, this forced convection makes it possible to attain satisfactory homogeneity within the working chamber 7.

Thus, the enclosure 1 is capable of being used as an incubator.

Moreover, in order to clean the working chamber 7, it is enough to take hold of the propeller 11 and to withdraw it without any dismantling operation being necessary.

Cleaning of the working chamber 7 is therefore more simple than in the case where the propeller is driven by a shaft passing through the inner envelope 5.

In addition, the structure of the fan 10 does not require any infractuosity to be created in the walls of the inner envelope 5 which would also hamper the cleaning operation.

When the cleaning of the working chamber 7 is finished, it is enough to place the propeller 11 back in the centre of the bottom 16. The complementary reliefs 25 and 27, which form indexing means, making it possible to position the propeller 11 in the centre of the bottom 16.

Finally, it is interesting to note that the structure of the fan 10 makes it possible to use the enclosure 1 with or without forced convection. In the latter case, it is enough to withdraw the propeller 11, the means 12 then being inactive.

According to a variant not shown, the reliefs 25 and 27 are removed, the centring being provided automatically when the means 12 are activated.

In another variant not shown, the propeller 11 may not include a permanent magnet, it being driven solely by the creation of eddy currents in the propeller 11 by the rotating magnetic field produced by the means 12. In this case, the propeller 11 comprises at least one part made from an electrically conducting material.

In yet another variant not shown, the propeller 11 comprises means to create a magnetic field rotating with respect to the propeller about the axis A. These means may comprise an electrical source and windings supplied by the latter.

In this case, the means 12 of FIG. 1 are replaced, for example, by a permanent magnet which, by cooperation with the rotating magnetic field, will make the propeller 11 rotate about the axis A.

According to another variant illustrated in FIG. 3, the blades 21 each have an “aircraft wing” profile with a substantially horizontal lower surface 37 and an upper surface 38 with concavity directed downwards. Each upper surface 38 of blade 21 is therefore inclined at least partly with respect to the axis A. On rotation of the propeller in the direction 31, a partial vacuum will be created above the upper surfaces 38 of the blades 21 tending to lift the propeller 11.

In yet another variant not shown, the means 12 for creating a rotating magnetic field and heating means 30 are placed above the upper wall 34 of the envelope 5 and the propeller 11 is placed under the upper wall 34. The means 12 then comprise one or more permanent magnet(s) in order to keep the propeller 11 in contact with the wall 34 against the effect of gravity, including in the absence of a rotating magnetic field created by the means 12.

According to the embodiment of FIG. 4, the enclosure 1 comprises at least one propeller 11 placed inside a shelf 40 of the working chamber 7. This shelf 40 is intended to support products to be treated in the working chamber 7.

The shelf 40 is hollow and comprises a horizontal lower wall 41 and a horizontal upper wall 42 between which the propeller 11 is placed. The walls 41 and 42 have openings 43 in order to enable the atmosphere of the working chamber 7 to flow through the shelf 40.

The lower face 26 of the hub 20 of the propeller 11 rests on the upper surface 44 of the lower wall 41. Indexing reliefs 25 and 27, such as those described above, are provided on the one hand on the lower face 26 of the hub 20 and the upper surface 44 of the lower wall 41, and on the other hand on the upper face 45 of the hub 20 and on the lower surface 46 of the upper wall 42.

The propeller 11 no longer includes a permanent magnet in its hub 20 but several permanent magnets 24 each carried by one of its blades 21. The magnetic fields created by these magnets 24 are substantially radial with respect to the axis A of the propeller 11.

The shelf 40 is supported on shelf supports 48 provided on the side walls 32 of the inner envelope 5. The shelf 40 rests freely on these shelf supports 48.

The means 12 for creating a rotating magnetic field comprise elements 49 placed in the thermal insulation 6 at the same level as the shelf 40, substantially at the centre of each side wall 32 of the inner envelope 5.

The fan 10 formed by the propeller 11 and the associated means 12 makes it possible, as above, to make the atmosphere of the working chamber 7 move.

The working chamber 7 is designed so that it can be equipped with several shelves 40 such as that described above and such that this arrangement can be combined with that described with respect to FIGS. 1 and 2.

More generally, the principles above can be applied to making the atmosphere move of a working chamber which is not heated but, for example, cooled.

1. Working enclosure (1), of the type comprising at least one envelope (5) delimiting the inside of a working chamber (7), and at least one fan (10) for making the atmosphere of the working chamber move, the fan comprising a propeller (11), which is placed inside the working chamber in order to rotate about a geometrical axis of rotation (A), and a motor (11, 12) with a rotating magnetic field comprising a stator located outside the working chamber, and a rotor mounted so as to rotate with the propeller as one piece and made to rotate by the rotating magnetic field, characterized in that the propeller forms the rotor.

2. Enclosure according to claim 1, characterized in that the propeller (11) comprises blades (21), the upper surfaces (38) of which are inclined at least partially with respect to its axis of rotation (A) in order to produce a local partial vacuum above the propeller, tending to lift it.

3. Enclosure according to claim 1, characterized in that it comprises means (25, 27) for indexing the position of the propeller with respect to the support surface (28, 44).

4. Enclosure according to claim 1, characterized in that the propeller (11) rests on a support surface (28, 44) located in the working chamber (7).

5. Enclosure according to claim 4, characterized in that the propeller rests freely on at least one support (16, 48) located in the working chamber (7).

6. Enclosure according to claim 5, characterized in that the propeller rests directly on the said support (16) which provides the said support surface (28).

7. Enclosure according to claim 4, characterized in that it comprises at least one shelf (40) placed in the working chamber, the shelf comprising a lower wall (41) and an upper wall (42) between which the propeller (11) is housed, the lower wall (41) providing the said support surface (44).

8. Enclosure according to claims 5 and 7 taken together, characterized in that the propeller rests on the support (48) via the lower wall (41) of the shelf.

9. Working enclosure according to claim 1, characterized in that it comprises at least one element (30) for heating the atmosphere of the enclosure of the working chamber (7).

10. Enclosure according to claim 1, characterized in that it comprises at least one element for cooling the atmosphere of the working chamber.

11. Enclosure according to claim 1, characterized in that the stator (12) is a stator for producing a rotating magnetic field in order to make the propeller (11) rotate.

12. Enclosure according to claim 1, characterized in that the propeller (11) comprises at least one permanent magnet (24).
